(19) United States
(12) Patent Application Publication
(10) Pub. No.: US 2006/0261335 A1
(43) Pub. Date: Nov. 23, 2006

(54) Liquid crystal display device

(75) Inventors: Tadaki Nakahori, Kumamoto (JP); Yuusuke Uchida, Kumamoto (JP); Kensuke Nagayama, Kumamoto (JP); Nobuaki Ishiga, Kumamoto (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Chiyoda-ku (JP)

(21) Appl. No.: 11/360,589

(22) Filed: Feb. 24, 2006

(30) Foreign Application Priority Data
May 23, 2005 (JP) 2005-148993

(51) Int. Cl. H01L 29/04

(52) U.S. Cl. 257/59

(57) ABSTRACT

An object of the present invention is to provide a liquid crystal display device that is capable of preventing anomalous growth of a protective insulating film when the protective insulating film is formed to cover a conductive film that was formed by patterning an amorphous conductive film into given shape with a certain etchant. A liquid crystal display device according to an example of the present invention includes a glass substrate having a thin film transistor formed on its upper surface, a color filter substrate having an opposing electrode formed on its upper surface, and a liquid crystal sandwiched between the glass substrate and the color filter substrate. A pixel electrode is connected to the drain electrode of a thin film transistor. Also, the pixel electrode is covered by a protective insulating film having transparency. The pixel electrode contains an oxide compound containing In and Zn.

### BACKGROUND OF THE INVENTION

1. Field of the Invention

The present invention relates to liquid crystal display devices, and particularly to a liquid crystal display device that has a protective insulating film formed to prevent short-circuits between electrodes.

2. Description of the Background Art

A liquid crystal display device is formed of an active-matrix array substrate having thin film transistors arranged in a matrix on a transparent insulative substrate of, e.g., glass, a color filter substrate having opposing electrodes, and a layer of liquid crystal sandwiched between them.

Such liquid crystal display devices are produced on a commercial basis as flat panel displays and are applied to notebook personal computers, office-automation monitors, and the like.

In a liquid crystal display device thus structured, a given voltage is applied between the opposing electrode and the pixel electrodes formed on the array substrate (including reflective electrodes made of, e.g., Al alloy, in the case of a reflective display device or a semi-transmissive display device). Then, the orientation of the liquid crystal molecules changes to allow a display of images (see Japanese Patent Application Laid-Open No. 2003-50389).

In the manufacture of such liquid crystal display devices, different etchants are used to pattern the pixel electrodes depending on the material of the pixel electrodes. For example, when the pixel electrodes are formed of an amorphous transparent conductive film, a weak acid, such as oxalic acid, must be used. On the other hand, when the pixel electrodes are formed of a crystalline transparent conductive film, a strong acid, such as aqua regia, must be used.

By the way, gate electrodes and source electrodes exist under the pixel electrodes, with insulating film formed therebetween. In this structure, when at least the gate electrodes or the source electrodes are made of a material containing Al alloy or Mo alloy in order to reduce resistance, then the use of a strong acid like aqua regia as the etchant to pattern the pixel electrodes causes display defects.

That is, the strong acid, such as aqua regia, passes through pinholes in the insulating film under the pixel electrodes to reach the underlying gate electrodes etc. made of such material. Then, the strong acid erodes the gate electrodes etc. The erosion of the gate electrodes etc. causes display defects.

Thus, when Al alloy, for example, is adopted as the material of the gate electrodes etc., the etchant used to pattern the pixel electrodes must be a weak acid like oxalic acid. Accordingly, the pixel electrodes must be formed of an amorphous ITO film (a transparent conductive film) that can be etched with a weak-acid etchant like oxalic acid (see Japanese Patent Application Laid-Open No. 2003-51496).

Now, if conductive foreign matter, such as metal, exists between the color filter substrate and the array substrate, the opposing electrode and pixel electrode may be short-circuited to cause display defects like dot defects. In order to prevent such display defects, a protective insulating film is formed to cover the pixel electrodes (including reflective electrodes in the case of a reflective display device or a semi-transmissive display device).

In this way, when an Al alloy, for example, is adopted as the material of the gate electrodes etc., the pixel electrodes must be made of an ITO film that is amorphous at least when the etching process is performed.

However, when the pixel electrodes are patterned by etching the amorphous ITO with oxalic acid, for example, crystalline ITO, which slightly exists in the amorphous ITO, forms as a residue in the areas from which the ITO film has been removed. It has been found that the grain-like ITO residue in the areas from which the ITO film has been removed causes anomalous growth of the protective insulating film formed to cover the pixel electrodes.

Also, suppose that a silicon nitride film is formed as the protective insulating film over the pixel electrodes made of an amorphous ITO film. Then, during the formation of the silicon nitride film, plasma dissociation of ammonia and hydrogen gas occurs to generate hydrogen radicals. It has been found that the hydrogen radicals cause reduction of In on the ITO film (on the pixel electrodes) and the silicon nitride film anomalously grows on the pixel electrodes.

Thus, the anomalous growth of the protective insulating film occurs not only in the areas from which ITO has been removed but also on the ITO film, which results in display defects of the liquid crystal display device.

### SUMMARY OF THE INVENTION

An object of the present invention is to provide a liquid crystal display device that is capable of preventing anomalous growth of a protective insulating film when the protective insulating film is formed to cover a conductive film that was formed by patterning an amorphous conductive film into given shape with a certain etchant.

According to a first aspect of the present invention, a liquid crystal display device includes a first substrate, a second substrate, a liquid crystal, a pixel electrode, and a protective insulating film. The first substrate has a thin film transistor formed thereon. The second substrate is placed opposite the first substrate and has an opposing electrode formed thereon. The liquid crystal is sandwiched between the first substrate and the second substrate. The pixel electrode is connected to the drain electrode of the thin film transistor. The protective insulating film has transparency and covers the pixel electrode. The pixel electrode contains an oxide compound containing In and Zn.

The pixel electrode can be patterned in the absence of crystal grains (crystalline oxide) in an amorphous film. Accordingly, even when the pixel electrode is etched (patterned) with an oxalic-acid-based etchant, no etching residue remains after the etching. This prevents the anomalous growth of the protective insulating film formed after that.

According to a second aspect of the present invention, a liquid crystal display device includes a first substrate, a second substrate, a liquid crystal, a pixel electrode, a reflective electrode, a transparent conductive film, and a protective insulating film. The first substrate has a thin film transistor formed thereon. The second substrate is placed opposite the first substrate and has an opposing electrode with transparency formed thereon. The liquid crystal is sandwiched between the first substrate and the second substrate. The pixel electrode is connected to the drain electrode of the thin film transistor. The reflective electrode is connected to the pixel electrode. The transparent conductive film is formed on the reflective electrode. The protective insulating film has transparency and covers the transparent conductive film. The transparent conductive film contains an oxide compound containing In and Zn.

The transparent conductive film can be patterned in the absence of crystal grains (crystalline oxide) in an amorphous film. Accordingly, even when the transparent conductive film is etched (patterned) with an oxalic-acid-based etchant, no etching residue forms after the etching. This prevents the anomalous growth of the protective insulating film formed after that.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing in a see-through manner the structure of an array substrate of a liquid crystal display device according to a first preferred embodiment;

FIG. 2 is a cross-sectional view showing the structure of the array substrate of the liquid crystal display device of the first preferred embodiment;

FIG. 3 is a cross-sectional view showing a part of the structure of the liquid crystal display device of the first preferred embodiment;

FIG. 4 is a cross-sectional view used to describe a method of manufacturing the liquid crystal display device of the first preferred embodiment;

FIGS. 5 and 6 are see-through plan views used to describe the liquid crystal display device manufacturing method of the first preferred embodiment;

FIG. 7 is a cross-sectional view used to describe the liquid crystal display device manufacturing method of the first preferred embodiment;

FIG. 8 is a see-through plan view used to describe the liquid crystal display device manufacturing method of the first preferred embodiment;

FIGS. 9 to 12 are cross-sectional views used to describe the liquid crystal display device manufacturing method of the first preferred embodiment;

FIG. 13 is a cross-sectional view showing the structure of an array substrate of a liquid crystal display device according to a second preferred embodiment;

FIG. 14 is a cross-sectional view showing the structure of an array substrate of a liquid crystal display device according to a third preferred embodiment;

FIG. 15 is a see-through plan view used to describe a method of manufacturing the liquid crystal display device of the third preferred embodiment;

FIG. 16 is a cross-sectional view used to describe the liquid crystal display device manufacturing method of the third preferred embodiment;

FIG. 17 is a see-through plan view used to describe the liquid crystal display device manufacturing method of the third preferred embodiment; and

FIG. 18 is a cross-sectional view used to describe the liquid crystal display device manufacturing method of the third preferred embodiment.

### DESCRIPTION OF THE PREFERRED EMBODIMENTS

The present invention will now be specifically described referring to the diagrams illustrating the preferred embodiments.

### First Preferred Embodiment

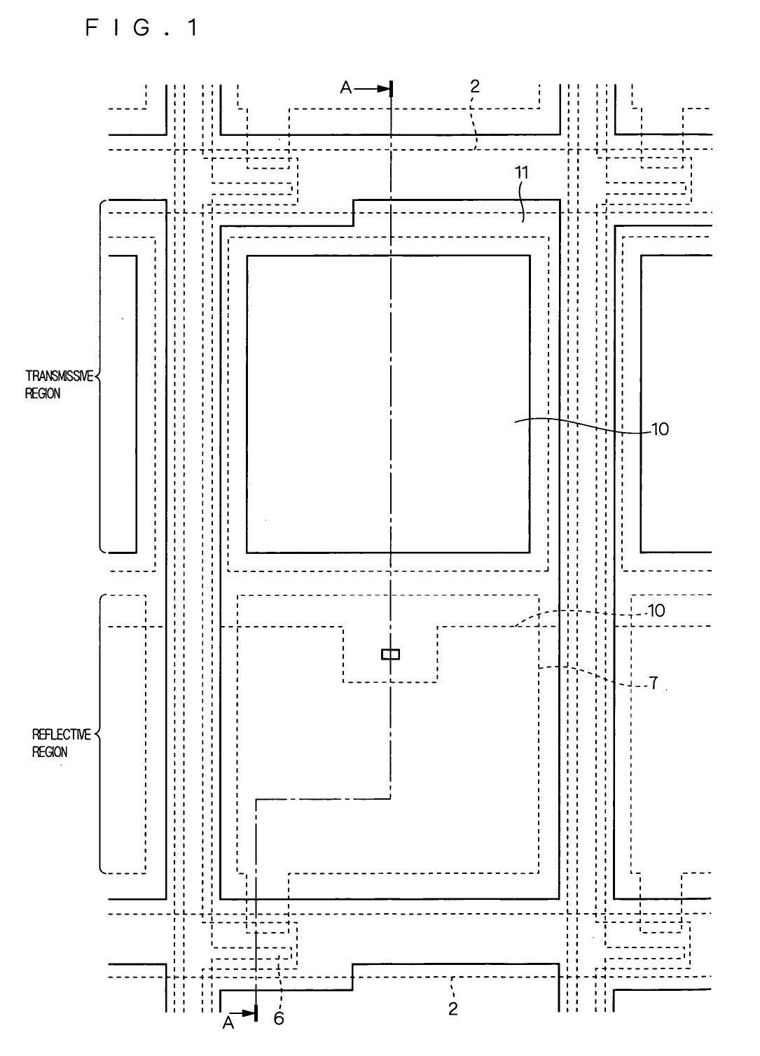

FIG. 1 is a plan view showing in a see-through manner a part of an active-matrix array substrate of a liquid crystal display device according to a first preferred embodiment.

The liquid crystal display device of this preferred embodiment has gate electrodes 2 and source electrodes 6 arranged in a matrix (FIG. 1 shows only a part of the matrix). A thin film transistor is formed in the vicinity of an intersection of a gate electrode 2 and a source electrode 6. The thin film transistor includes the gate electrode 2, the source electrode 6, and a drain electrode 7. The individual areas sectioned by the gate electrodes 2 and source electrodes 6 form pixels.

The liquid crystal display device of this preferred embodiment is a semi-transmissive liquid crystal display device in which each pixel has a reflective region and a transmissive region. The reflective region includes a pixel electrode 10 and a reflective electrode 11, and the transmissive region includes only the pixel electrode 10.

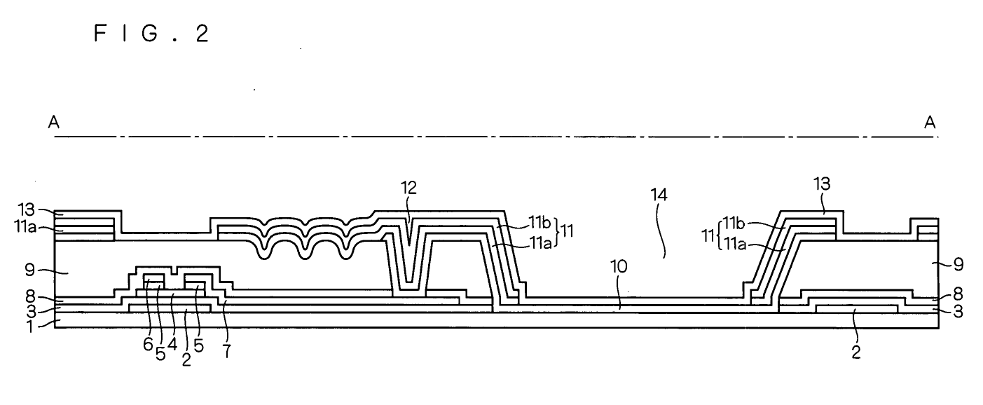

FIG. 1 is a plan view showing in a see-through manner a part of the active-matrix array substrate thus structured, and FIG. 2 shows the section taken along line A-A of FIG. 1. As shown in FIG. 2, the array substrate is formed of a glass substrate 1 and individual elements formed on the glass substrate 1.

As shown in FIG. 2, the gate electrode 2 is formed on the glass substrate 1, or a transparent insulative substrate of glass, for example. A gate insulating film 3 is formed covering the gate electrode 2. On a given area of the gate insulating film 3, a semiconductor layer 4 and an ohmic contact layer 5 are stacked in this order to form a layered structure having a given pattern. The source electrode 6 and the drain electrode 7, patterned in given shape, lie on the ohmic contact layer 5 and the gate insulating film 3.

The gate electrode 2, the source electrode 6, the drain electrode 7, and the like form the thin film transistor.

In order to reduce the resistance, one or some of the gate electrode 2, source electrode 6, and drain electrode 7 contain Mo or Al. Thus, the gate electrode 2, for example, contains Mo or Al. Accordingly, as mentioned earlier, the etchant used to etch the pixel electrode 10 later must be a weak acid such as oxalic acid. Also, because the pixel electrode 10 is thus etched with a weak-acid etchant, the pixel electrode 10, at least before the etching, must be amorphous so that it can be etched with the weak-acid etchant.

The ohmic contact layer 5 has been removed from the area other than the area where the source electrode 6 and the drain electrode 7 are formed.

Also, as shown in FIG. 2, a passivation film 8 of inorganic material, e.g., a silicon nitride film, is formed over the source electrode 6 and the drain electrode 7. On the passivation film 8, an organic film 9 is formed which is made of, e.g., acrylic resin, and which has irregularities in its surface. The pixel electrode 10 of a given pattern is formed on the organic film 9, and a reflective electrode 11 of a given pattern is formed further on the pixel electrode 10.

The pixel electrode 10 is an amorphous conductive film having transparency at least in the etching stage. The pixel electrode 10 is connected to the underlying drain electrode 7 through a contact hole 12 formed in the passivation film 8 and the organic film 9. The gate insulating film 3, the passivation film 8, and the organic film 9 are partially removed to expose part of the surface of the glass substrate 1 (the exposed area is referred to as a transmissive region 14), and the pixel electrode 10 extends to cover the region 14.

The reflective electrode 11 has a two-layered structure including a lower reflective electrode 11a and an upper reflective electrode 11b. The reflective electrode 11 is absent in the transmissive region 14. Also, because the reflective electrode 11 is formed on the organic film 9 having surface irregularities, the reflective electrode 11, too, has irregularities. The irregularities of the reflective electrode 11 can cause diffused reflection of light.

Also, as shown in FIG. 2, a protective insulating film 13 having transparency is formed to cover the organic film 9, the pixel electrode 10, and the reflective electrode 11.

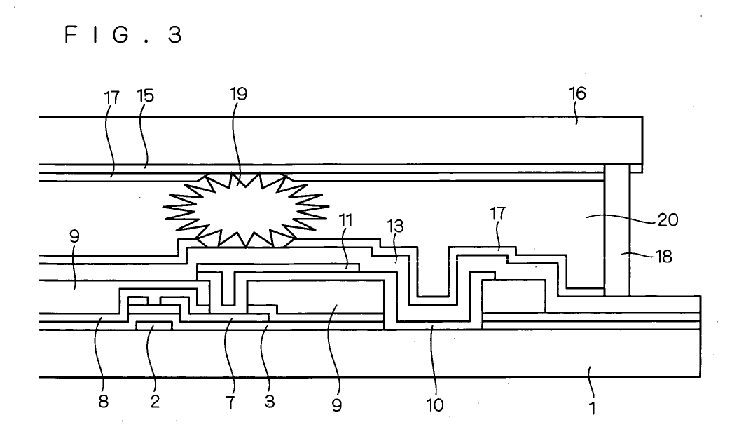

As shown in the cross-sectional view of FIG. 3, the liquid crystal display device further includes a color filter substrate 16 placed opposite the array substrate thus structured.

The color filter substrate 16 has opposing electrodes 15 formed thereon, and an alignment layer 17 is applied to cover the opposing electrode 15. An alignment layer 17 is applied also to the uppermost layer of the array substrate (glass substrate 1). The color filter substrate 16 and the array substrate are bonded together with a sealing material 18, with a liquid crystal 20, containing conductive foreign matter 19, sandwiched between the two substrates.

As shown in FIG. 3, the conductive foreign matter 19 is present between the pixel electrode 10 (or the reflective electrode 11) and the opposing electrode 15. Even if the conductive foreign matter 19 breaks through the alignment layers 17, the pixel electrode 10 (or the reflective electrode 11) and the opposing electrode 15 are not short-circuited because the pixel electrode 10 (or the reflective electrode 11) is covered by the protective insulating film 13. This provides a liquid crystal display device that is free from display defects caused by such short-circuits.

In the liquid crystal display device thus structured according to the preferred embodiment, the pixel electrode 10 contains the following components.

That is, in this preferred embodiment, the pixel electrode 10 is a transparent conductive film made of an oxide compound that contains In and Zn (IZO), or an oxide compound that contains In, Zn, and Sn. As mentioned above, the pixel electrode 10 is amorphous at least in the stage of etching.

The inclusion of Zn oxide in the pixel electrode 10 makes the crystallization temperature relatively high. This makes it possible to pattern the pixel electrode 10 in the absence of crystal grains (crystalline oxide) in the amorphous film. This prevents etching residues remaining after the etching even when the pixel electrode 10 is etched (patterned) with an oxalic-acid-based etchant.

Thus, the absence of etching residues avoids the anomalous growth of the protective insulating film 13 that would be caused by grain-like ITO residues as described earlier, not only on the pixel electrode 10 made of an amorphous transparent conductive film but also in the area where the transparent conductive film has been removed by the patterning to expose the organic film 9.

When the pixel electrode 10 is an amorphous transparent conductive film composed of an oxide compound containing In, Zn, and Sn, then it is preferable to restrict the percent-by-weight ratio of ZnO with respect to the total amount of In2O3, SnO2, and ZnO, for example.

This is because, when the percent-by-weight ratio of ZnO with respect to the total amount is too small, the crystallization temperature is likely to be lowered (i.e., crystallization is likely to occur readily) though the formation of residues after the etching is prevented, which makes the processing of the pixel electrode 10 difficult. On the other hand, when the percent-by-weight ratio of ZnO with respect to the total amount is too large, the resistance value of the pixel electrode 10 increases.

The inventors have confirmed that the formation of etching residues is prevented and the above-mentioned problems (i.e., the problems of crystallization temperature and resistance value) do not occur when the percent-by-weight ratio of ZnO to the total amount of In2O3, SnO2, and ZnO is in the range not less than 1 wt % nor more than 10 wt %.

For example, when the percent-by-weight ratio of In2O3:SnO2:ZnO=89:5:6, the crystallization temperature of the pixel electrode 10 is around 250° C. When the crystallization temperature of the pixel electrode 10 is this high, the formation of etching residues is prevented and no problem arises about the processibility of the pixel electrode 10.

The transparent conductive film, which is amorphous in the etching stage, may be crystallized in a final stage of the array processing because of a thermal treatment for the formation of the protective insulating film 13 or for the stabilization of transistor performance.

Next, a method of manufacturing the liquid crystal display device of this preferred embodiment will be described.

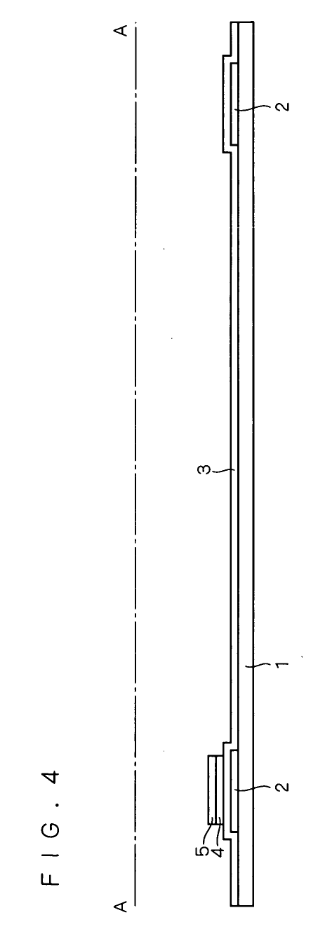

First, as shown in FIG. 4, the given pattern of gate electrodes 2 is formed on the glass substrate 1. More specifically, the process is performed as shown below.

For example, a refractory metal, such as Mo or an Mo alloy, is formed on the glass substrate 1 to a thickness of 200 to 300 nm by a known sputtering process using an Ar gas. The sputtering adopts the following conditions. That is, the sputtering adopts a DC magnetron sputtering method, with a film formation power density of 3 W/cm², an Ar gas flow rate of 100 sccm, a film formation pressure of 0.2 to 0.4 Pa, and a film formation temperature of 100 to 180° C.

After the formation of the refractory metal film, a first photolithography process is performed to form a resist pattern on the refractory metal. Then, using the resist pattern as a mask, the refractory metal is etched using a known etchant containing nitric acid+acetic acid+phosphoric acid+pure water. The resist pattern is then removed, whereby the given pattern of gate electrodes 2 is formed on the glass substrate (FIG. 4).

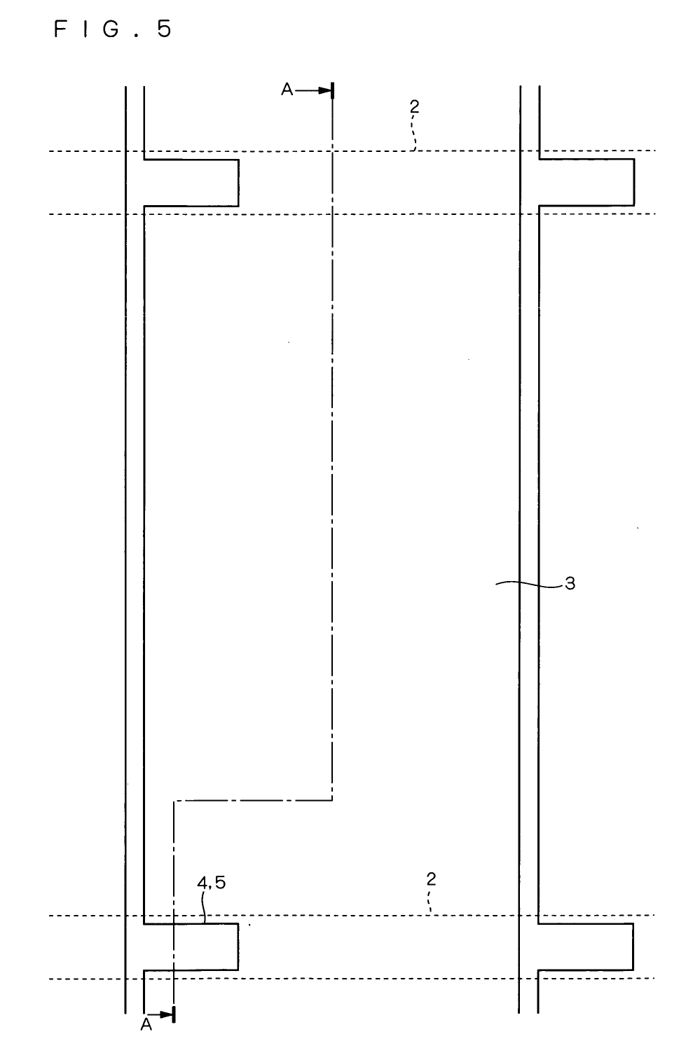

Next, as shown in FIG. 4, the gate insulating film 3, the semiconductor layer 4, and the ohmic contact layer 5 are formed in this order on the glass substrate 1, thus covering the gate electrode 2. Subsequently, the semiconductor stacked layers, including the semiconductor layer 4 and the ohmic contact layer 5, are patterned into given shape. FIG. 5 is a plan view of the liquid crystal display device processed through the steps described so far. FIG. 4 corresponds to the cross section taken along line A-A of FIG. 5. FIG. 5 shows the gate electrodes 2 with broken line because they exist under other layers.

More specifically, the gate insulating film 3, the semiconductor layer 4, and the ohmic contact layer 5 are formed as shown below.

For example, silicon nitride, for the gate insulating film 3, is formed on the glass substrate 1 to a thickness of 300 to 500 nm by chemical vapor deposition (CVD), whereby the gate electrode 2 is covered. Then, also by CVD, amorphous silicon, for the semiconductor layer 4, is formed over the gate insulating film 3 to a thickness of 100 to 200 nm. Furthermore, also by CVD, n+-type amorphous silicon doped with phosphorus as impurity is formed as the ohmic contact layer 5 to a thickness of 30 to 50 nm over the semiconductor layer 4.

Next, a second photolithography process is performed to form a resist pattern on the ohmic contact layer 5. Then, using the resist pattern as a mask, the semiconductor layer 4 and the ohmic contact layer 5 are etched by a know dry-etching process using a fluorine-based gas. The resist pattern is then removed, whereby the gate insulating film 3 and the semiconductor stacked layers of the given pattern (the semiconductor layer 4 and the ohmic contact layer 5) are formed over the glass substrate 1 (FIGS. 4 and 5).

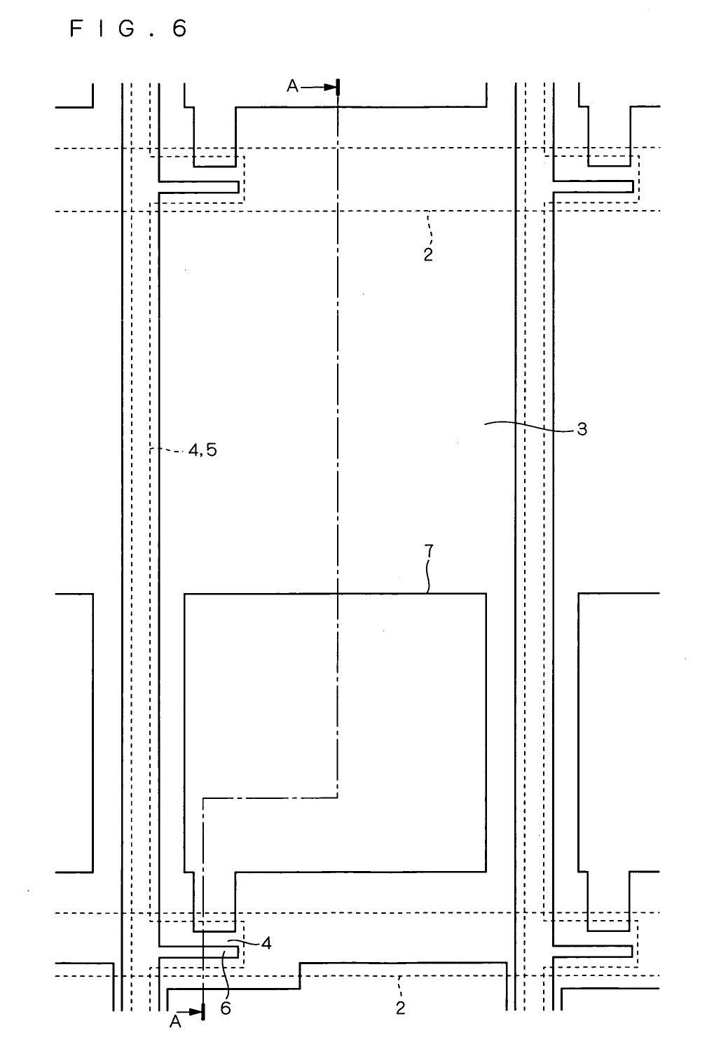

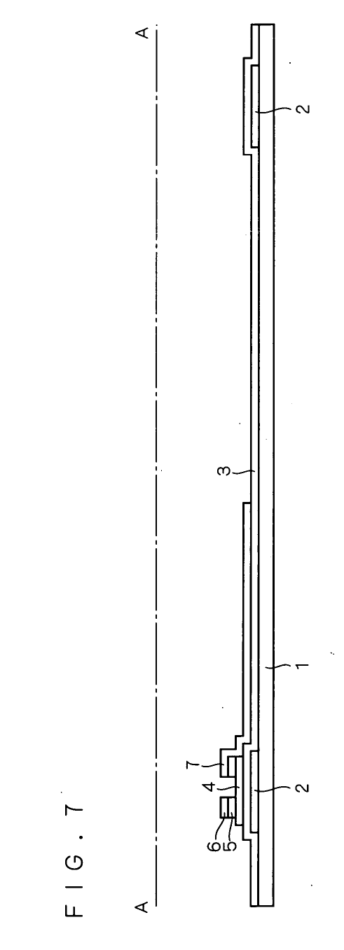

After the formation of the gate insulating film 3, the semiconductor layer 4, and the ohmic contact layer 5, the source electrode 6 of a given pattern and the drain electrode 7 of a given pattern are formed on the gate insulating film 3 and the ohmic contact layer 5. FIG. 6 is a plan view of the liquid crystal display device processed through the steps described so far. FIG. 7 shows the cross section taken along line A-A of FIG. 6. FIG. 6 shows the gate electrode 2 and the semiconductor stacked layers (the semiconductor layer 4 and the ohmic contact layer 5) with broken line.

Specifically, the source electrode 6 and the drain electrode 7 are formed as shown below.

For example, a thin metal film (e.g., a film of Mo), for the source electrode 6 and the drain electrode 7, is formed by sputtering to a thickness of 200 to 400 nm over the gate insulating film 3 and the ohmic contact layer 5.

Subsequently, a third photolithography process is performed to form a resist pattern on the thin metal film. Then, using the resist pattern as a mask, the thin metal film is etched using a known etchant containing nitric acid+acetic acid+phosphoric acid+pure water. By the etching process, the source electrode 6 of a given pattern and the drain electrode 7 of a given pattern are formed on the gate insulating film 3 and the ohmic contact layer 5 (FIGS. 6 and 7).

Next, using the resist pattern, the source electrode 6, and the drain electrode 7 as a mask, the exposed part of the ohmic contact layer 5 is etched by a known dry-etching process using a fluorine-based gas. The resist pattern is then removed (FIGS. 6 and 7).

Next, the passivation film 8 is formed over the gate insulating film 3, the source electrode 6, and the drain electrode 7 formed over the glass substrate 1. Then, the organic film 9, having photosensitivity, is formed on the passivation film 8. The irregularities 9a are then formed in a given surface area of the organic film 9. Then, openings are formed as the contact hole 12 having a given opening area and passing through the organic film 9 and the passivation film 8, and as the transmissive region 14 having a given opening area and passing through the organic film 9, the passivation film 8, and the gate insulating film 3.

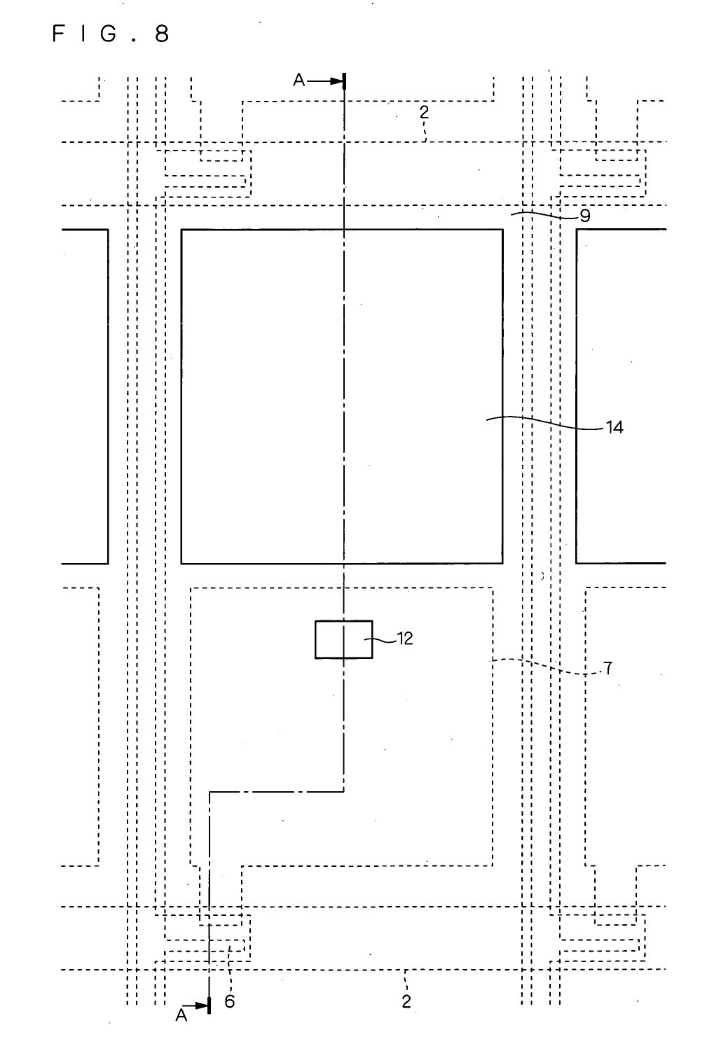

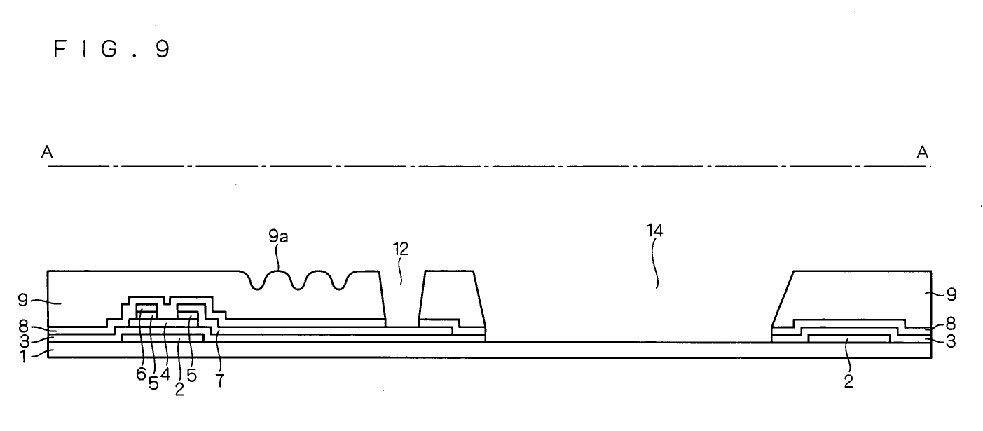

FIG. 8 is a plan view of the liquid crystal display device processed through the steps described so far. FIG. 9 shows the cross section taken along line A-A of FIG. 8. FIG. 8 shows the underlying components 2, 6, 7, etc. with broken line.

Now, as can be seen from FIG. 9, the drain electrode 7 is exposed at the bottom of the contact hole 12. Also, the glass substrate 1 is exposed at the bottom of the opening as the transmissive region 14. The irregularities 9a are formed to a given depth from the surface of the organic film 9 (i.e., not passing through the organic film 9).

Specifically, the passivation film 8, and the organic film 9 having the irregularities 9a and the openings as the contact hole 12 and the transmissive region 14 are formed as shown below.

For example, a silicon nitride film, for the passivation film 8, is formed by CVD to a thickness of about 100 nm, thus covering the components 3, 6, 7, etc. on the glass substrate 1. Then, PC335, produced by JSR Corporation, is applied as the organic film 9 by spin coating onto the passivation film 8 to a thickness of 3.2 to 3.9 μm.

Subsequently, a fourth photolithography process is performed to form the irregularities 9a and the openings in the organic film 9. The openings are formed in the organic film 9 in the positions corresponding to the contact hole 12 and the transmissive region 14. The passivation film 8 is exposed at the bottoms of the openings.

Next, using the organic film 9 as a mask, the passivation film 8 and the gate insulating film 3 are etched by a known dry-etching process using a fluorine-based gas. The etching process forms the openings as the contact hole 12 exposing the drain electrode 7 at its bottom and the transmissive region 14 exposing the glass substrate 1 at its bottom (FIGS. 8 and 9).

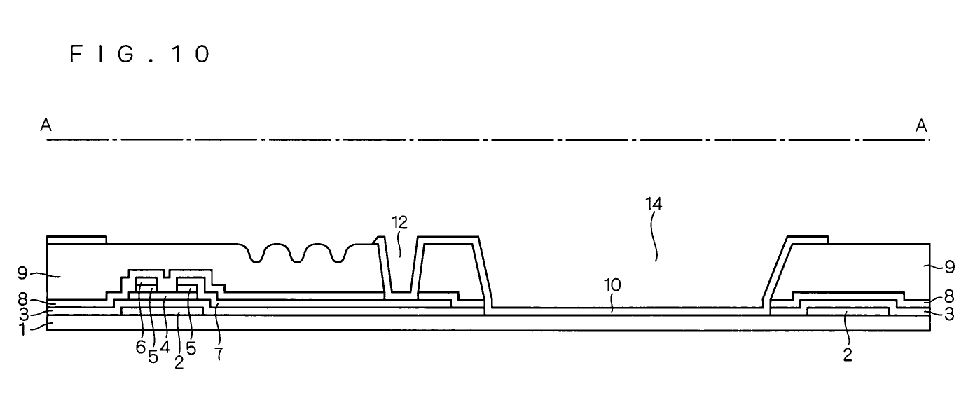

After the formation of the organic film 9 with the contact hole 12 formed therethrough, the pixel electrode 10 of a given pattern is formed on the organic film 9. The pixel electrode 10 is a conductive film having transparency. FIG. 10 is a cross-sectional view illustrating the structure obtained after the formation of the pixel electrode 10.

As shown in FIG. 10, the pixel electrode 10 is formed also on the sides and at the bottom of the contact hole 12. The pixel electrode 10 is thus electrically connected to the drain electrode 7. The pixel electrode 10 is formed also on the sides and at the bottom of the opening of the transmissive region 14.

Specifically, the pixel electrode 10 is formed as shown below.

For example, a conductive film having transparency, for the pixel electrode 10, is formed by sputtering to a thickness of about 100 nm over the organic film 9 (including the openings as the contact hole 12 and the transmissive region 14). The conductive film having transparency is an amorphous ITZO film that contains indium oxide (In2O3), zinc oxide (ZnO), and tin oxide (SnO2).

After the formation of the conductive film having transparency, a fifth photolithography process is performed to form a resist pattern on the conductive film having transparency. Then, using the resist pattern as a mask, the conductive film having transparency is etched by using a known oxalic-acid-based etchant. By this etching process, the pixel electrode 10 of a given pattern is formed on the organic film 9 (including the openings as the contact hole 12 and the transmissive region 14) (FIG. 10).

The inclusion of the Zn oxide in the pixel electrode 10 makes the crystallization temperature relatively high. Accordingly, no crystal grains (crystalline oxide) are present in the amorphous film (i.e., the amorphousness of the pixel electrode 10 is enhanced). It is thus possible to prevent formation of etching residues after the etching even when the pixel electrode 10 is etched (patterned) with an oxalic-acid-based etchant.

Thus, because a weak acid, like oxalic acid, is used as the etchant, components like the gate electrode 2 and the source electrode 6, which are made of material containing Al alloy or Mo alloy, are not damaged even if the gate insulating film 3 and the passivation film 8 under the pixel electrode 10 have film defects like pinholes.

After the formation of the pixel electrode 10, the resist pattern is removed, and a thin metal film is formed to cover the pixel electrode 10 at least. The thin metal film has a light reflecting property in the visible range. The thin metal film is patterned into given shape to form the reflective electrode 11.

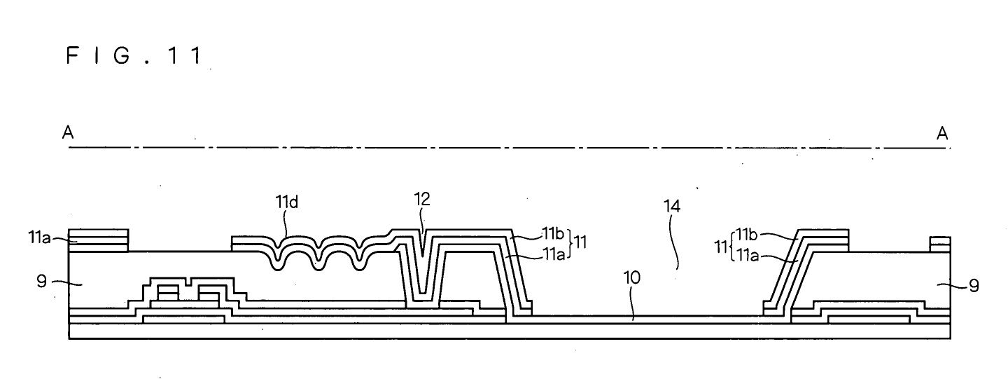

The plan view of the liquid crystal display device thus processed is known from FIG. 1. FIG. 11 shows the cross section taken along line A-A of the structure. FIG. 1, too, shows the underlying components 2, 6, 7, 10, etc. with broken line.

As can be seen from FIGS. 1 and 11, the pixel electrode 10 is exposed at the bottom of the opening as the transmissive region 14. The part of the reflective electrode 11 located on the irregularities 9a of the organic film 9 has irregularities 11d because of the irregularities 9a. The reflective electrode 11 has a two-layered structure including the lower reflective electrode 11a and the upper reflective electrode 11b.

Specifically, the reflective electrode 11 is formed as shown below.

For example, a thin metal film, for the lower reflective electrode 11a, is formed by sputtering over the pixel electrode 10 to a thickness of about 100 nm. The thin metal film (the lower reflective electrode 11a) is made of, e.g., Mo or an Mo alloy obtained by adding a small amount of another element to Mo. The Mo alloy may be an MoNb alloy obtained by adding Nb to Mo, or an MoW alloy obtained by adding W to Mo.

Subsequently, a thin metal film, for the upper reflective electrode 11b, is formed by sputtering to a thickness of about 300 nm on the lower reflective electrode 11a. The thin metal film (the upper reflective electrode 11b) has a high light reflecting property in the visible range. The thin metal film (the upper reflective electrode 11b) is made of, e.g., Al or an Al alloy obtained by adding a small amount of another element to Al. The Al alloy may be an AlCu alloy obtained by adding 0.1 to 2 wt % of Cu to Al.

After the formation of the two-layered thin metal film, a sixth photolithography process is performed to form a resist pattern on the two-layered thin metal film. Then, using the resist pattern as a mask, the two-layered thin metal film is etched using an etchant containing phosphoric acid+nitric acid+acetic acid. The resist pattern is then removed. The reflective electrode 11 having a given pattern is thus formed through the etching process (FIGS. 1 and 11).

As shown in FIGS. 1 and 11, the reflective electrode 11 is absent at the bottom of the opening as the transmissive region 14, while the pixel electrode 10 is present there.

After the formation of the reflective electrode 11, the protective insulating film 13 having a given pattern is formed to cover the pixel electrode 10, the reflective electrode 11, the organic film 9, and the like. FIG. 2 corresponds to the A-A section of the liquid crystal display device processed in this way. The protective insulating film 13 is formed in order to prevent short-circuiting between the pixel electrode 10 (or the reflective electrode 11) and the opposing electrodes 15 provided on the color filter substrate 16. The protective insulating film 13 has transparency.

Specifically, the protective insulating film 13 is formed as shown below.

For example, a silicon nitride film, for the protective insulating film 13, is formed by plasma CVD to cover the organic film 9, the pixel electrode 10, the reflective electrode 11, and the like.

As described above, during the formation (patterning) of the pixel electrode 10, no grain-like etching residue forms. Accordingly, the silicon nitride film does not anomalously grow during the formation of the silicon nitride film.

After the formation of the silicon nitride film, a seventh photolithography process is performed to form a resist pattern on the silicon nitride film. Then, using the resist pattern as a mask, the silicon nitride film is etched. Subsequently, the resist pattern is removed. The protective insulating film 13 of a given pattern is thus formed through the etching process (FIG. 2).

The process of forming the silicon nitride film includes a thermal treatment. Accordingly, the transparent conductive film, which is amorphous in the etching, may be crystallized.

As mentioned earlier, the protective insulating film 13 is formed in order to prevent short-circuiting between the opposing electrode 15 and the pixel electrode 10 (or the reflective electrode 11) through the conductive foreign matter 19 contained in the liquid crystal 20. Therefore, the area on the glass substrate 1 from which the silicon nitride film (protective insulating film 13) is removed is limited to, e.g., an area for terminals (not shown) that does not face the opposing electrodes 15 through the liquid crystal 20.

After the process steps described so far, the glass substrate 1 (array substrate) structured as shown in FIG. 2 is bonded to the color filter substrate 16 having the opposing electrodes 15 and the alignment layer 17 formed thereon, with the two substrates 1 and 16 facing each other through the liquid crystal 20 containing the conductive foreign matter 19 (FIG. 3).

The liquid crystal display device of this preferred embodiment is thus completed through the sequence of process steps.

As described so far, in the liquid crystal display device of this preferred embodiment, the pixel electrode 10 (transparent conductive film) contains In oxide and Zn oxide.

Accordingly, no crystalline oxide exists in the transparent conductive film that is amorphous before the etching, so that no etching residue forms during the etching process for the formation of the pixel electrode 10. Therefore, the protective insulating film 13 formed after that does not anomalously grow. This prevents clouding in the display area and prevents display defects caused by lowered reflectivity.

The description above has shown an example that adopts a silicon nitride film as the protective insulating film 13. However, as mentioned earlier, when a silicon nitride film is formed as the protective insulating film on the pixel electrode 10 formed of an amorphous ITO film, plasma dissociation of ammonia and hydrogen gas occurs to generate hydrogen radicals during the formation of the silicon nitride film. The hydrogen radicals cause reduction of In on the ITO film (on the pixel electrode 10), which may lead to the anomalous growth of the silicon nitride film on the pixel electrode 10.

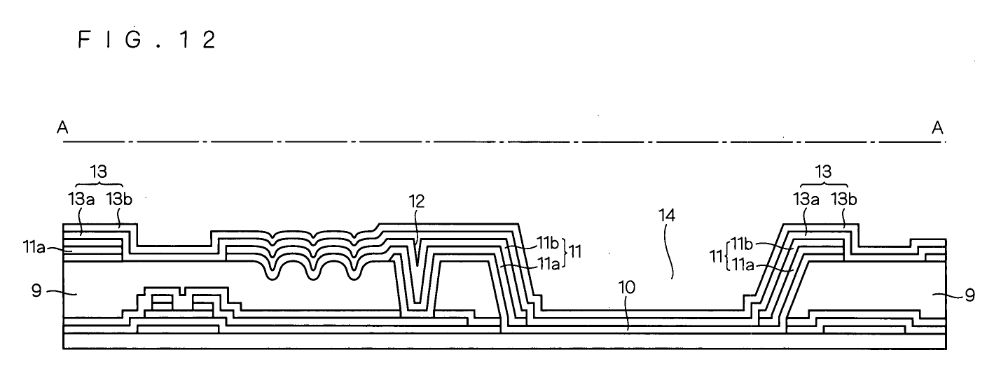

Accordingly, in order to avoid the reduction of In, a silicon oxide film may be adopted as the protective insulating film 13, or a stacked film including a silicon oxide film and a silicon nitride film formed in this order may be adopted as the protective insulating film 13. FIG. 12 shows a cross section of a structure that adopts such a layered film including a silicon oxide film and a silicon nitride film formed in this order as the protective insulating film 13.

For example, the formation of the stacked film is achieved by forming a silicon oxide film 13a by plasma CVD and then forming a silicon nitride film 13b on the silicon oxide film 13a also by plasma CVD. The stacked film is then patterned into given shape (i.e., the protective insulating film 13 is formed) (FIG. 12).

Thus, forming the protective insulating film 13 as the stacked film including silicon oxide and silicon nitride films formed in this order avoids the anomalous growth of the silicon nitride film and provides the protective insulating film 13 with superior moisture resistance.

The description above has shown an application of the preferred embodiment to a semi-transmissive liquid crystal display device. However, needless to say, this preferred embodiment is applicable also to transmissive liquid crystal display devices.

### Second Preferred Embodiment

There is a technique in which, since the opposing electrodes 15 has transparency, a transparent conductive film is formed on the reflective electrode 11 to improve display characteristics. The present invention is applicable also to liquid crystal display devices thus structured.

That is, the transparent conductive film contains an oxide compound containing In and Zn.

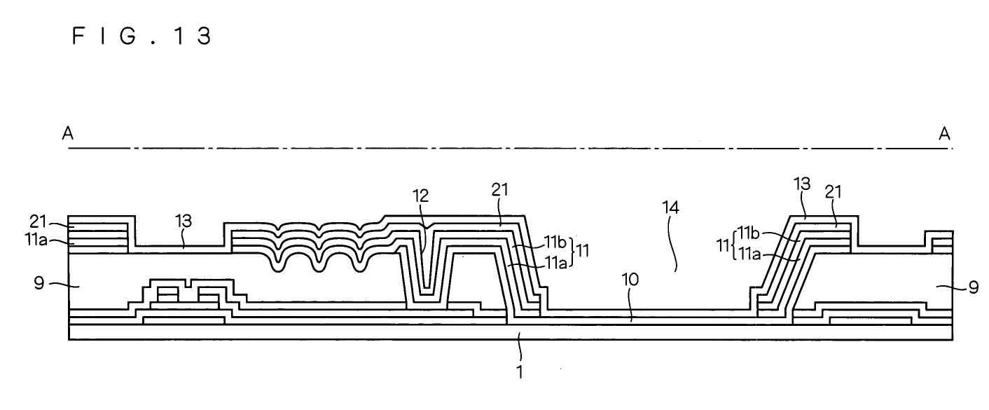

FIG. 13 is a cross-sectional view showing the structure of a liquid crystal display device of a second preferred embodiment (specifically, the structure of its array substrate). In this preferred embodiment, the same components as those described in the first preferred embodiment are shown at the same reference characters.

As described before, in order to reduce the resistance, one or some of the gate electrode 2, the source electrode 6, and the drain electrode 7 contain Mo or Al. Thus, the gate electrode 2, for example, contains Mo or Al. Accordingly, as described above, the etchant used to etch the transparent conductive film later must be a weak acid, such as oxalic acid. Also, because the etching of the transparent conductive film thus uses a weak-acid etchant, the transparent conductive film must be amorphous at least before the etching so that it can be etched by the weak-acid etchant.

As can be seen by comparing FIGS. 2 and 13, the liquid crystal display device of this preferred embodiment is structured in the same manner as the display device of the first preferred embodiment except that a transparent conductive film 21 is formed on the reflective electrode 11. Accordingly, only the difference will be described in detail below, and the same components as those of the first preferred embodiment will not be described again.

In the liquid crystal display device of this preferred embodiment, as shown in FIG. 13, the transparent conductive film 21 is formed between the reflective electrode 11 and the protective insulating film 13. As mentioned above, since the opposing electrodes 15 has transparency, the transparent conductive film 21 is formed on the reflective electrode 11 in order to improve display characteristics.

The liquid crystal display device of this preferred embodiment (specifically, the transparent conductive film 21) is formed as shown below. This preferred embodiment will only describe process steps that are different from those of the manufacturing method of the liquid crystal display device of the first preferred embodiment, without describing the same process steps.

Now, through the sequence of process steps described in the first preferred embodiment, the two-layered, thin metal film is formed as the reflective electrode 11. At this point of time, the two-layered thin metal film is not patterned yet (i.e., the reflective electrode 11 does not have the given pattern yet). The process steps preceding the formation of the two-layered thin metal film are the same as those described in the first preferred embodiment.

Next, a transparent conductive material is formed on the two-layered thin metal film. Subsequently, the transparent conductive material and the two-layered thin metal film are patterned to form the reflective electrode 11 and the transparent conductive film 21 (FIG. 13). Specifically, the process is performed as shown below.

For example, the transparent conductive material, for the transparent conductive film 21, is formed by sputtering to a thickness of 3 to 15 nm over the two-layered thin metal film. The transparent conductive material (transparent conductive film 21) is an amorphous ITZO film that contains indium oxide (In2O3), zinc oxide (ZnO), and tin oxide (SnO2).

After the formation of the transparent conductive material film, a photolithography process is performed to form a resist pattern on the transparent conductive material. Then, using the resist pattern as a mask, the transparent conductive material is etched with a known oxalic-acid-based etchant. Then, using the same resist pattern as a mask, the two-layered thin metal film is etched with an etchant that contains phosphoric acid+nitric acid+acetic acid. The resist pattern is then removed.

The etching process steps form the reflective electrode 11 having a given pattern (more specifically, the two-layered reflective electrode 11 including the lower reflective electrode 11a and the upper reflective electrode 11b), and also forms the transparent conductive film 21 having a given pattern on the reflective electrode 11 (FIG. 13).

The inclusion of Zn oxide in the transparent conductive film 21 makes the crystallization temperature relatively high. Accordingly, no crystal grains (no crystalline oxide) exist in the amorphous film (i.e., the amorphousness of the transparent conductive film 21 is enhanced). Accordingly, even when the transparent conductive film 21 is etched (patterned) with an oxalic-acid-based etchant, no etching residue remains after the etching process.

After the formation of the reflective electrode 11 and the transparent conductive film 21, the protective insulating film 13 having a given pattern is formed to cover the pixel electrode 10, the transparent conductive film 21, and the organic film 9 (FIG. 13). The protective insulating film 13 is formed for the purpose of preventing short-circuiting between the pixel electrode 10 (or the transparent conductive film 21) and the opposing electrodes 15 formed on the color filter substrate 16. The protective insulating film 13 has transparency.

Specifically, the protective insulating film 13 is structured and formed as described in the first preferred embodiment, which is not described here again.

In this way, no grain-like etching residue forms during the formation of the transparent conductive film 21. Accordingly, the protective insulating film 13 does not anomalously grow during the formation of the protective insulating film 13.

The process of forming the protective insulating film 13 includes a thermal treatment. Accordingly, the transparent conductive film, which is amorphous when etched, may be crystallized.

After the process steps described so far, the glass substrate 1 structured as shown in FIG. 13 is bonded to the color filter substrate 16 having the opposing electrodes 15 and the alignment layer 17 formed thereon, with the two substrates 1 and 16 facing each other through the liquid crystal 20 containing the conductive foreign matter 19.

The liquid crystal display device of this preferred embodiment is thus completed through the sequence of process steps.

Thus, in the liquid crystal display device of this preferred embodiment, the transparent conductive film 21 contains Zn oxide as well as In oxide.

Accordingly, no crystalline oxide exists in the transparent conductive film 21 that is amorphous before the etching, so that no etching residue forms in the etching process for the patterning of the transparent conductive film 21. Therefore, the protective insulating film 13 formed after that does not anomalously grow. This prevents clouding in the display area and prevents display defects caused by lowered reflectivity.

In the liquid crystal display device of this preferred embodiment, the pixel electrode 10 may contain Zn oxide, or may contain no Zn oxide. However, as described in the first preferred embodiment, when the pixel electrode 10, which is amorphous before etching, contains Zn oxide as well as In oxide, no etching residue forms during the etching of the pixel electrode 10 as described in the first preferred embodiment, and no etching residue forms during the etching of the transparent conductive film 21.

Accordingly, when the pixel electrode 10, which is amorphous before etching, contains Zn oxide, it is possible to more certainly prevent the anomalous growth of the protective insulating film 13.

This preferred embodiment has shown an application of the present invention to a semi-transmissive liquid crystal display device. However, needless to say, the present invention is applicable also to reflective liquid crystal display devices.

### Third Preferred Embodiment

The first and second preferred embodiments provide semi-transmissive liquid crystal display devices by separately providing the reflective electrodes 11. However, a semi-transmissive liquid crystal display device may be constructed without the reflective electrodes 11, but by providing the drain electrodes 7 with a reflecting function.

In a third preferred embodiment, in a semi-transmissive liquid crystal display device having drain electrodes 7 with a reflecting function, the pixel electrodes 10 contain In oxide and Zn oxide in the manner described in the first preferred embodiment.

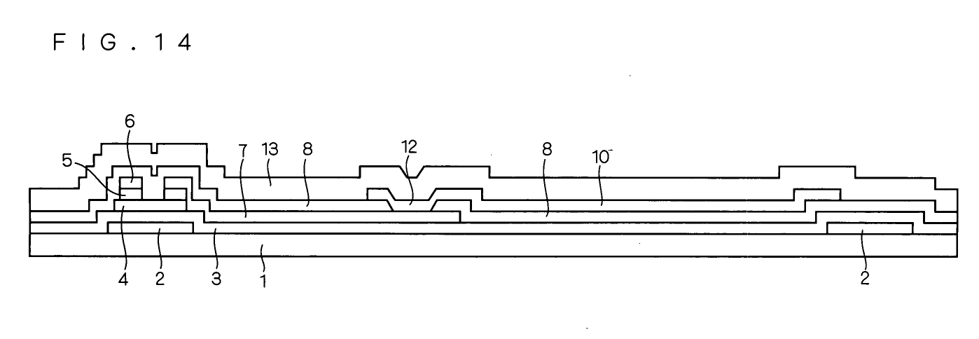

FIG. 14 is a cross-sectional view of the liquid crystal display device (specifically, its array substrate) according to this preferred embodiment. The same components as those described in the first preferred embodiment are shown at the same reference characters in this preferred embodiment.

The liquid crystal display device of this preferred embodiment does not have the reflective electrode 1, and so the organic film 9 is omitted as shown in FIG. 14.

The drain electrode 7 has a reflecting function, and the drain electrode 7 serves the function of the reflective electrode 11. Accordingly, preferably, the drain electrode 7 of this preferred embodiment has a larger area than the drain electrode 7 of the first preferred embodiment, so as to prevent deterioration of image quality.

Also, because the reflective electrode 11 and the organic film 9 are absent as shown in FIG. 14, the protective insulating film 13 is formed to cover the passivation film 8 and the pixel electrode 10 in this preferred embodiment.

As shown in FIG. 14, in the liquid crystal display device of this preferred embodiment, in the transmissive region 14, the gate insulating film 3 and the passivation film 8 are present between the glass substrate 1 and the pixel electrode 10. This is for the reason below.

That is, the array substrate of the first preferred embodiment has the organic film 9 that has an opening as the transmissive region 14, and the etching process is performed using the organic film 9 as a mask. However, the organic film 9 is absent in this preferred embodiment. Accordingly, in this preferred embodiment, in the transmissive region 14, the gate insulating film 3 and the passivation film 8 are not removed, but are left between the glass substrate 1 and the pixel electrode 10.

The presence of the insulating films between the glass substrate 1 and the pixel electrode 10 raises no problem about the operation of the liquid crystal display device.

In other respects, the liquid crystal display device of this preferred embodiment is almost the same as that of the first preferred embodiment and therefore not described in detail here again.

Next, a method of manufacturing the liquid crystal display device of this preferred embodiment is described. The source electrode 6 and the drain electrode 7 are formed in the manner described in the first preferred embodiment, and then a silicon nitride film for the passivation film 8 is formed also in the manner described in the first preferred embodiment. Accordingly, these process steps are not described again here.

In this preferred embodiment, the drain electrode 7 serves the function of the reflective electrode 11. Therefore, in order to prevent deterioration of image quality, it is preferable to make the area of the drain electrode 7 as large as possible.

After the steps above, the passivation film 8 is formed to cover the gate insulating film 3, the source electrode 6, the drain electrode 7, etc., formed over the glass substrate 1. The contact hole 12 having a given opening area is then formed to pass through the passivation film 8.

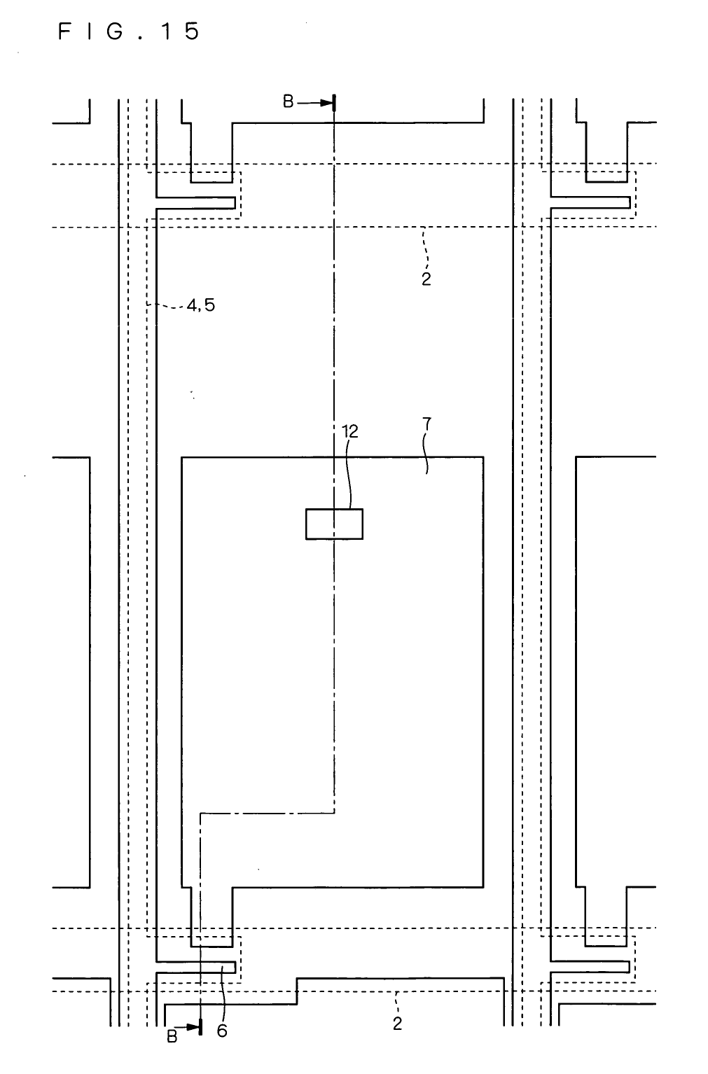

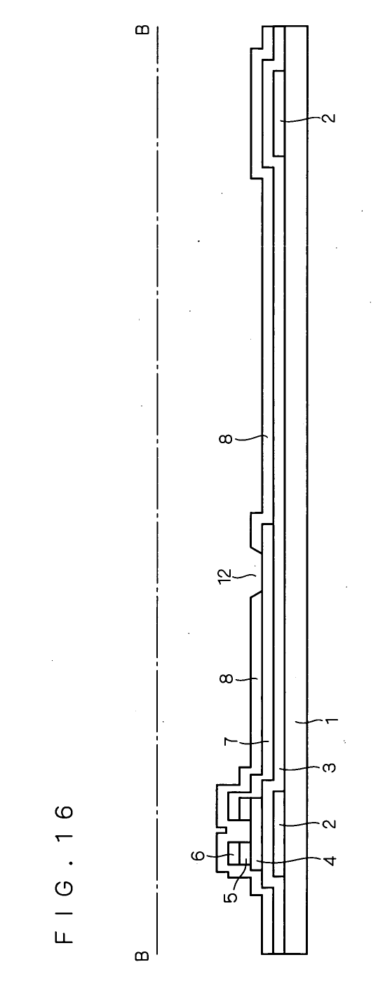

FIG. 15 is a plan view showing the liquid crystal display device thus processed. FIG. 16 shows the cross section taken along line B-B of FIG. 15. In FIG. 15, the components 2, 4, 5, etc., existing below the passivation film 8, are shown by broken line (however, the source electrode 6 and the drain electrode 7 are shown by solid line for the convenience of the drawing).

As can be seen from FIG. 16, the drain electrode 7 is exposed at the bottom of the contact hole 12.

Specifically, the passivation film 8 and the contact hole 12 are formed as shown below.

For example, a silicon nitride film, for the passivation film 8, is formed by CVD to a thickness of 300 to 400 nm over the components 3, 6, 7, etc. formed on the glass substrate 1.

Subsequently, a photolithography process is performed to form a resist pattern on the silicon nitride film (passivation film 8). Then, using the resist pattern as a mask, the passivation film 8 is etched by a known dry-etching process using a fluorine-based gas. By the etching process, the contact hole 12 is formed in the passivation film 8, and the drain electrode 7 is exposed at the bottom of the contact hole 12 (FIGS. 15 and 16).

After the formation of the passivation film 8 and the contact hole 12 formed therein, the pixel electrode 10 of a given pattern is formed on the passivation film 8. The pixel electrode 10 is a conductive film having transparency.

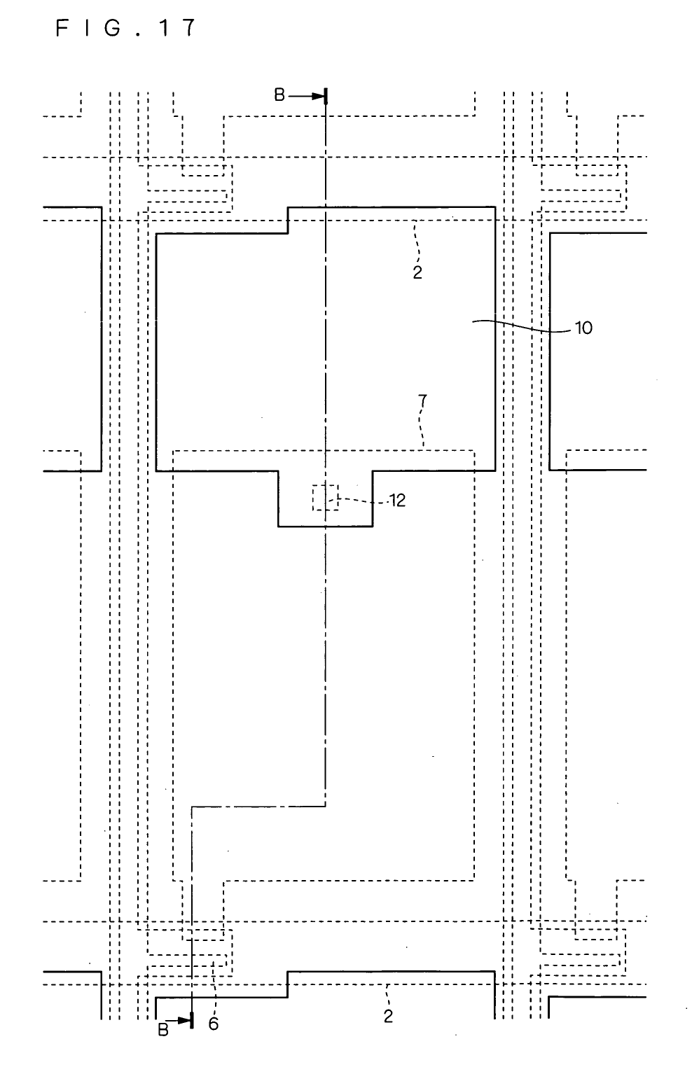

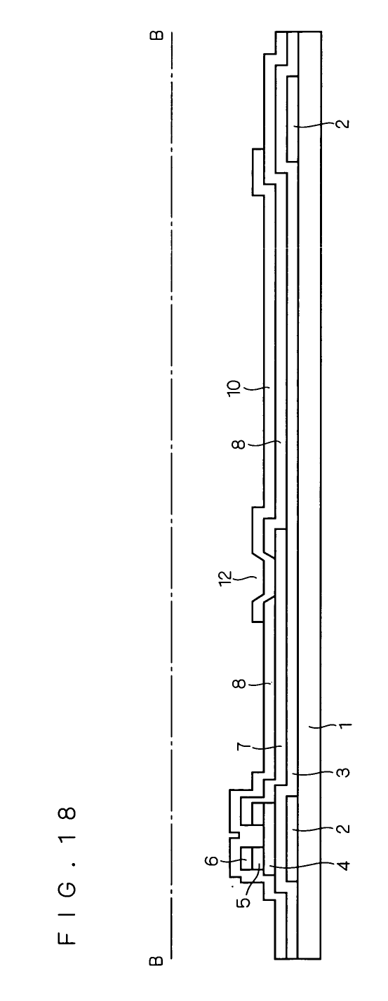

FIG. 17 is a plan view showing the liquid crystal display device thus processed. FIG. 18 shows the cross section taken along line B-B of FIG. 17. In FIG. 17, the components 2, 6, 7, 12, etc. existing under the pixel electrode 10 are shown by broken line.

As shown in FIG. 18, the pixel electrode 10 is electrically connected to the drain electrode 7 in the contact hole 12.

Specifically, the pixel electrode 10 is formed as shown below.

For example, a conductive film having transparency, for the pixel electrode 10, is formed by sputtering to a thickness of about 100 nm over the passivation film 8. The conductive film having transparency is an amorphous ITZO film that contains indium oxide (In2O3), zinc oxide (SnO), and tin oxide (SnO2).

After the formation of the conductive film having transparency, a photolithography process is performed to form a resist pattern on the conductive film having transparency. Then, using the resist pattern as a mask, the conductive film having transparency is etched with a known oxalic-acid-based etchant, which is followed by the removal of the resist pattern. By this etching process, the pixel electrode 10 having a given pattern is formed on the passivation film 8 (FIGS. 17 and 18).

The inclusion of Zn oxide in the pixel electrode 10 makes the crystallization temperature relatively high. Accordingly, no crystal grains (crystalline oxide) exist in the amorphous film (i.e., the amorphousness of the pixel electrode 10 is enhanced). Thus, no etching residue remains after the etching process even when the pixel electrode 10 is etched (patterned) with an oxalic-acid-based etchant.

After the formation of the pixel electrode 10, the protective insulating film 13 having a given pattern is formed to cover the pixel electrode 10 and the like. FIG. 14 corresponds to a cross-sectional view of the liquid crystal display device processed through these steps.

Specifically, the protective insulating film 13 is formed in the manner described in the first preferred embodiment, which is not described here again.

As above, no grain-like etching residue forms during the formation of the pixel electrode 10. This avoids the anomalous growth of the protective insulating film 13 during the formation of the protective insulating film 13.

The process of forming the protective insulating film 13 includes a thermal treatment. Accordingly, the transparent conductive film, which is amorphous when etched, may be crystallized.

After the process steps above, the glass substrate 1 structured as shown in FIG. 14 is bonded to the color filter substrate 16 having the opposing electrodes 15 and the alignment layer 17 formed thereon, with the two substrates 1 and 16 facing each other through the liquid crystal 20 containing the conductive foreign matter 19.

The liquid crystal display device of this preferred embodiment is thus completed through the sequence of process steps.

As described so far, in the liquid crystal display device of this preferred embodiment, the pixel electrode 10 (conductive film having transparency) contains Zn oxide as well as In oxide.

Accordingly, no crystalline oxide exists in the conductive film having transparency that is amorphous before the etching, so that no etching residue forms in the etching process for the formation of the pixel electrode 10. Therefore, the protective insulating film 13 formed after that does not anomalously grow. This prevents clouding in the display area and prevents display defects caused by lowered reflectivity.

The liquid crystal display device of this preferred embodiment, having no reflective electrode 11 and no organic film 9, allows simpler manufacturing process as compared with the liquid crystal display device of the first preferred embodiment.

While the invention has been described in detail, the foregoing description is in all aspects illustrative and not restrictive. It is understood that numerous other modifications and variations can be devised without departing from the scope of the invention.

What is claimed is:

1. A liquid crystal display device comprising:
a first substrate having a thin film transistor formed thereon;
a second substrate placed opposite said first substrate and having an opposing electrode formed thereon;
a liquid crystal sandwiched between said first substrate and said second substrate;
a pixel electrode connected to a drain electrode of said thin film transistor; and
a protective insulating film having transparency and covering said pixel electrode,
said pixel electrode comprising an oxide compound containing In and Zn.

2. A liquid crystal display device comprising:
a first substrate having a thin film transistor formed thereon;
a second substrate placed opposite said first substrate and having an opposing electrode with transparency formed thereon;
a liquid crystal sandwiched between said first substrate and said second substrate;
a pixel electrode connected to a drain electrode of said thin film transistor;
a reflective electrode connected to said pixel electrode;
a transparent conductive film formed on said reflective electrode; and
a protective insulating film having transparency and covering said transparent conductive film,
said transparent conductive film comprising an oxide compound containing In and Zn.

3. The liquid crystal display device according to claim 1, wherein said pixel electrode further contains Sn oxide.

4. The liquid crystal display device according to claim 2, wherein said transparent conductive film further contains Sn oxide.

5. The liquid crystal display device according to claim 3, wherein said pixel electrode contains the Zn oxide at a percent by weight of not less than 1 wt % nor more than 10 wt % with respect to a total amount.

6. The liquid crystal display device according to claim 4, wherein said transparent conductive film contains the Zn oxide at a percent by weight of not less than 1 wt % nor more than 10 wt % with respect to a total amount.

7. The liquid crystal display device according to claim 1, wherein said protective insulating film is a silicon nitride film.

8. The liquid crystal display device according to claim 2, wherein said protective insulating film is a silicon nitride film.

9. The liquid crystal display device according to claim 1, wherein said protective insulating film is a silicon oxide film.

10. The liquid crystal display device according to claim 2, wherein said protective insulating film is a silicon oxide film.

11. The liquid crystal display device according to claim 1, wherein said protective insulating film is a stacked film including a silicon oxide film and a silicon nitride film formed in this order.

12. The liquid crystal display device according to claim 2, wherein said protective insulating film is a stacked film including a silicon oxide film and a silicon nitride film formed in this order.

13. The liquid crystal display device according to claim 1, wherein said pixel electrode is amorphous.

14. The liquid crystal display device according to claim 2, wherein said transparent conductive film is amorphous.

15. The liquid crystal display device according to claim 1, wherein at least one of a gate electrode, a source electrode, and the drain electrode of said thin film transistor contains Al or Mo.

16. The liquid crystal display device according to claim 2, wherein at least one of a gate electrode, a source electrode, and the drain electrode of said thin film transistor contains Al or Mo.
